(19) United States
(12) Patent Application Publication
(10) Pub. No.: US 2024/0234107 A1
(43) Pub. Date: Jul. 11, 2024

(54) ELECTROSTATIC CHUCK, SUBSTRATE PROCESSING APPARATUS, AND MANUFACTURING METHOD OF ELECTROSTATIC CHUCK

(71) Applicant: Tokyo Electron Limited, Tokyo (JP)

(72) Inventors: Masato MINAMI, Nirasaki City (JP); Tomoya WATANABE, Nirasaki City (JP)

(21) Appl. No.: 18/399,821

(22) Filed: Dec. 29, 2023

(30) Foreign Application Priority Data
Jan. 5, 2023 (JP) 2023-000700

(51) Int. Cl. H01J 37/32; H02N 13/00

(52) U.S. Cl. CPC H01J 37/32715; H02N 13/00; H01J 2237/2007

(57) ABSTRACT

An electrostatic chuck having a support surface configured to support a substrate, wherein the support surface is configured by a plurality of protrusions that is formed at a same height and is arranged in a direction in which the support surface extends, wherein a distance between the plurality of protrusions adjacent to each other is in a range of 0.2 mm to 0.5 mm, and wherein, in a plan view of the support surface, an area occupancy rate of the plurality of protrusions in a 1 mm² unit of the support surface is in a range of 3% to 40%.

### CROSS-REFERENCE TO RELATED APPLICATION

This application is based upon and claims the benefit of priority from Japanese Patent Application No. 2023-000700, filed on Jan. 5, 2023, the entire contents of which are incorporated herein by reference.

### TECHNICAL FIELD

The present disclosure relates to an electrostatic chuck, a substrate processing apparatus, and a manufacturing method of the electrostatic chuck.

### BACKGROUND

Patent Document 1 discloses an electrostatic chuck for supporting a substrate inside a vacuum container (processing container). A chuck plate of this electrostatic chuck is configured as an elastic body made of a dielectric resin such as silicon. Further, an upper surface of the chuck plate undergoes embossing, thereby having a plurality of convex portions (protrusions).

Alternatively, in some cases, a substrate processing apparatus may employ an electrostatic chuck having a flat support surface that does not have a plurality of protrusions.

### PRIOR ART DOCUMENT

### Patent Document

Patent Document 1: International Publication No. 2020/115952

### SUMMARY

According to one embodiment of the present disclosure, there is provided an electrostatic chuck having a support surface configured to support a substrate, wherein the support surface is configured by a plurality of protrusions that is formed at a same height and is arranged in a direction in which the support surface extends, wherein a distance between the plurality of protrusions adjacent to each other is in a range of 0.2 mm to 0.5 mm, and wherein, in a plan view of the support surface, an area occupancy rate of the plurality of protrusions in a 1 mm² unit of the support surface is in a range of 3% to 40%.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a side cross-sectional view illustrating a plasma processing apparatus according to one embodiment.

FIG. 2A is an enlarged side cross-sectional view illustrating a part of an electrostatic chuck. FIG. 2B is an enlarged plan view illustrating a support surface of one configuration example. FIG. 2C is an enlarged plan view illustrating a support surface of another configuration example.

FIG. 3 is an enlarged side cross-sectional view illustrating a plurality of protrusions of the electrostatic chuck.

FIG. 4 is a flowchart illustrating a manufacturing method of the electrostatic chuck.

FIGS. 5A to 5D are first to fourth explanatory diagrams illustrating the manufacturing method of the electrostatic chuck.

FIGS. 6A and 6B are fifth and sixth explanatory diagrams illustrating the manufacturing method of the electrostatic chuck. FIG. 6C is an enlarged view illustrating each protrusion polished by a polishing process of the manufacturing method.

FIG. 7A is an enlarged cross-sectional view illustrating a state where a substrate is supported by the electrostatic chuck according to the present embodiment. FIG. 7B is an enlarged cross-sectional view illustrating a state where a substrate is supported by an electrostatic chuck according to a first comparative example. FIG. 7C is an enlarged cross-sectional view illustrating a state where a substrate is supported by an electrostatic chuck according to a second comparative example.

FIG. 8 is a graph illustrating simulation results of an electric field along a predetermined direction of the electrostatic chuck.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments for carrying out the present disclosure will be described with reference to the drawings. In each drawing, the same reference numerals may be given to the same components, and redundant descriptions may be omitted.

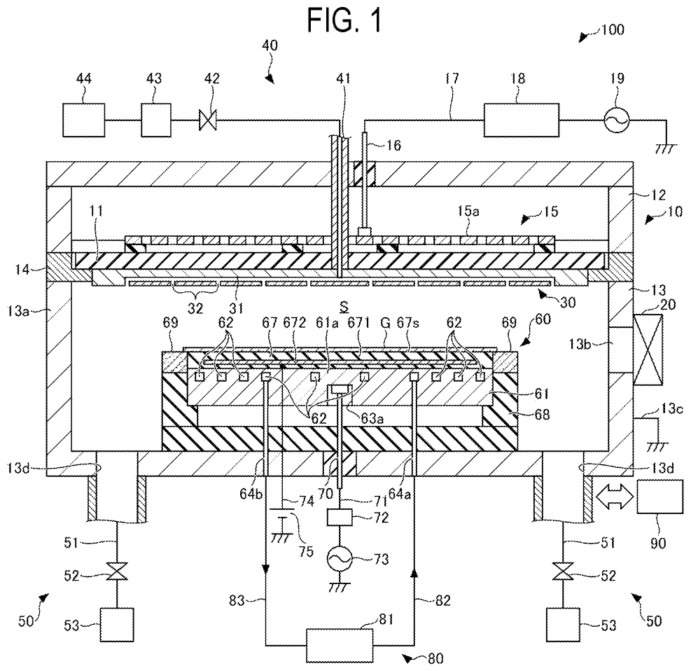

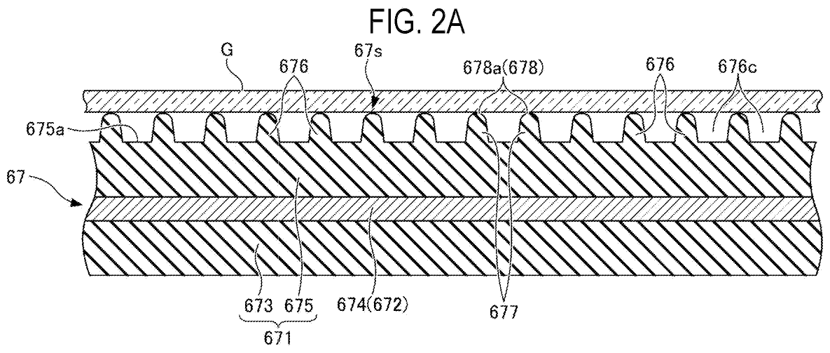

FIG. 1 is a side cross-sectional view illustrating a plasma processing apparatus according to one embodiment. As illustrated in FIG. 1, an electrostatic chuck 67 according to one embodiment is applied to a plasma processing apparatus 100 for a flat panel display (FPD), which is an example of a substrate processing apparatus. Examples of the FPD may include a liquid crystal display (LCD), an electro luminescence (EL), and a plasma display panel (PDP). Hereinafter, to facilitate understanding of the present disclosure, a configuration of this plasma processing apparatus 100 will first be described.

The plasma processing apparatus 100 is configured as an inductively coupled plasma (ICP) apparatus that performs various types of substrate processing on a flat panel display substrate (hereinafter simply referred to as substrate G), which has a square shape in a plan view. Examples of a material for the substrate may include glass and a transparent synthetic resin. Various types of substrate processing include etching and film formation using a chemical vapor deposition (CVD) method, and the like.

The planar dimension of the substrate G processed by the plasma processing apparatus 100 includes, for example, at least a range from approximately 1,500 mm×1,800 mm for the 6th generation to approximately 2,800 mm×3,100 mm for the 10th generation. A thickness of the substrate G is, for example, in a range of approximately 0.3 mm to several millimeters.

The plasma processing apparatus 100 illustrated in FIG. 1 includes a rectangular box-shaped processing container 10 and a substrate stage 60 which is accommodated in the processing container 10 and on which the substrate G is placed. Further, the plasma processing apparatus 100 includes a controller 90 that controls various components of the apparatus.

The processing container 10 includes a dielectric plate 11, an antenna container 12 provided above the dielectric plate 11 in a vertical direction, and a processing container main body 13 provided below the dielectric plate 11 in the vertical direction. The interior of the processing container 10 is divided into two upper and lower spaces by the dielectric plate 11. The antenna container 12 together with the dielectric plate 11 defines an antenna chamber. The processing container main body 13 together with the dielectric plate 11 defines a processing chamber S.

Further, the processing container 10 includes a support frame 14 in a shape of a rectangular frame sandwiched between the antenna container 12 and the processing container main body 13. The support frame 14 has a portion protruding inward of the processing container 10 and supports the dielectric plate 11 by this portion. The processing container 10 is grounded via a ground wire 13c.

The antenna container 12 and the processing container main body 13 are made of a metal such as aluminum. The dielectric plate 11 is made of ceramics such as alumina (Al₂O₃), or quartz.

A sidewall 13a of the processing container main body 13 is provided with a loading/unloading port 13b that enables loading and unloading of the substrate G into/from the interior of the processing container main body 13. The loading/unloading port 13b is opened and closed by a gate valve 20. When the gate valve 20 is open, a transfer device (not illustrated) loads or unloads the substrate G into/from the interior of the processing container main body 13 through the loading/unloading port 13b.

Further, a plurality of exhaust ports 13d connected to a gas exhauster 50 is provided in the bottom of the processing container main body 13. The gas exhauster 50 includes a plurality of gas exhaust pipes 51 connected to the plurality of exhaust ports 13d, an on/off valve 52 that opens and closes an exhaust path of each gas exhaust pipe 51, and an exhaust device 53 connected to each gas exhaust pipe 51. The exhaust device 53 includes a vacuum pump such as a turbo molecular pump, and evacuates the interior of the processing container main body 13 during substrate processing.

A shower head 30 is provided on a lower surface of the dielectric plate 11. The shower head 30 also serves as a support beam for supporting the dielectric plate 11. The shower head 30 is made of a metal such as aluminum. A surface of the shower head 30 may undergo a processing such as anodization. The shower head 30 includes a horizontally extending gas flow path 31 and a plurality of gas discharge holes 32 for communication between the gas flow path 31 and the processing chamber S located below the shower head 30 in the vertical direction.

A processing gas supplier 40 is connected to the shower head 30 to supply a gas to the gas flow path 31. The processing gas supplier 40 includes a gas supply pipe 41, an on/off valve 42 and flow controller 43 provided at intermediate positions of the gas supply pipe 41, and a processing gas source 44 located at an end of the gas supply pipe 41. In addition, when supplying a plurality of types of gases, the gas supply pipe 41 may be branched at an intermediate position thereof, each branch being provided with the on/off valve, flow controller, and processing gas source. During plasma processing, the plasma processing apparatus 100 supplies a gas from the processing gas source 44 to the gas flow path 31 of the shower head 30 through the gas supply pipe 41, and then discharges the gas into the processing chamber S from each gas discharge hole 32.

The processing container 10 includes a radio frequency antenna 15 in the interior of the antenna container 12. The radio frequency antenna 15 is constructed by forming an antenna wire 15a made of a conductive metal such as copper or aluminum in an annular or spiral shape.

A feeding member 16 extending upward of the antenna container 12 is connected to a terminal of the antenna wire 15a. A feeding line 17 is connected to an upper end of the feeding member 16. The feeding line 17 is in turn connected to a radio frequency power supply 19 through a matcher 18 that performs impedance matching. For example, the plasma processing apparatus 100 applies radio frequency power of 13.56 MHz from the radio frequency power supply 19 to the radio frequency antenna 15, thereby creating an induced electric field inside the processing container main body 13. This induced electric field plasmarizes a processing gas supplied from the shower head 30 to the processing chamber S, and ions and radicals in the plasma are supplied to the substrate G. The radio frequency power supply 19 serves as a plasma generation source, and a radio frequency power supply 73 (an example of a power supply) to be described later, which is connected to the substrate stage 60, serves as a bias power supply that attracts the generated ions and provides kinetic energy thereto. In this way, plasma is generated by using inductive coupling in an ion source and ion energy is controlled by a separate bias power supply connected to the substrate stage 60. Accordingly, it is possible to control plasma generation and ion energy independently of each other, thereby increasing the degree of freedom in substrate processing. In addition, the frequency of radio frequency power output from the radio frequency power supply 19 may be set appropriately within a range of 0.1 MHz to 500 MHz.

Meanwhile, the substrate stage 60 provided inside the processing container 10 (processing container main body 13) has a base 61 that forms a temperature regulation area. Further, the substrate stage 60 includes the electrostatic chuck 67, which is disposed on an upper surface of the base 61 to directly support the substrate G.

The base 61 is formed in a square shape in a plan view, and has approximately a same planar dimension as the substrate G placed on the substrate stage 60. For example, the length of the shorter side (first direction) of the base 61 is in a range of approximately 1,500 mm to 3,000 mm, and the length of the longer side (second direction) of the base 61 is in a range of approximately 1,800 mm to 3,400 mm. Further, a support surface 67s of the electrostatic chuck 67 is also formed in a square shape in a plan view depending on the substrate G, with dimensions set, for example, to be 1,400 mm or more for the shorter side (first direction) and 1,790 mm or more for the longer side (second direction).

The base 61 is a metal plate with high thermal conductivity and is made of, for example, aluminum, aluminum alloy, stainless steel, etc. The base 61 is placed on a rectangular member 68 made of an insulating material. The rectangular member 68 is fixed to a bottom plate of the processing container main body 13.

The base 61 has a temperature regulation medium flow path 62 therein. In addition, the substrate stage 60 is not limited to the temperature regulation medium flow path 62 but may have various other temperature regulators. For example, the temperature regulation area of the base 61 may have various configurations having only a heater or having both the temperature regulation medium flow path 62 and the heater.

Both ends of the temperature regulation medium flow path 62 are connected to a transfer pipe 64a for supplying a temperature regulation medium and a return pipe 64b for discharging the temperature regulation medium that has been raised in temperature by circulation through the temperature regulation medium flow path 62. A transfer flow path 82 and a return flow path 83 are respectively connected to the transfer pipe 64a and the return pipe 64b. Both the transfer flow path 82 and the return flow path 83 are connected to a chiller 81. The chiller 81 controls the temperature and discharge flow rate of the temperature regulation medium and also pumps the temperature regulation medium. The chiller 81, transfer flow path 82, and return flow path 83 form a dedicated temperature regulation source 80 for the base 61.

The plasma processing apparatus 100 may include a temperature sensor (not illustrated) such as a thermocouple on the electrostatic chuck 67 or the base 61 and may be configured to monitor the temperature of the substrate G. When detection information from the temperature sensor is transmitted to the controller 90, the controller 90 controls the chiller 81 based on the detection information to adjust the temperatures of the substrate stage 60 and the substrate G. In addition, a plurality of temperature regulation areas may be set in the base 61. In this case, different temperature regulation medium flow paths, chillers, and temperature regulation sources may be provided to correspond to the respective temperature regulation areas.

Further, the substrate stage 60 includes a heat transfer gas supplier (not illustrated) that supplies a heat transfer gas such as He gas between the electrostatic chuck 67 and the substrate G. The heat transfer gas supplier supplies the heat transfer gas to a lower surface of the substrate G through a plurality of through-holes (not illustrated) provided in the electrostatic chuck 67 and the base 61. This facilitates rapid heat transfer from the temperature-regulated substrate stage 60 to the substrate G via the heat transfer gas, thereby allowing for the control of the temperature regulation of the substrate G.

Further, the substrate stage 60 includes a plurality of lifting pins (not illustrated). The lifting pins are raised and lowered in the vertical direction by a lifting mechanism (not illustrated), and protrude upward from the support surface 67s of the electrostatic chuck 67 to receive and deliver the substrate G to/from the transfer device.

Further, a step portion is formed by the outer peripheries of the electrostatic chuck 67 and base 61 as well as an upper surface of the rectangular member 68, and a focus ring 69 in a shape of a rectangular frame is placed on this step portion. When the focus ring 69 is in position, an upper surface of the focus ring 69 is lower than an upper surface of the electrostatic chuck 67. The focus ring 69 is made of ceramics such as alumina, or quartz. When the substrate G is placed on the support surface 67s of the electrostatic chuck 67, an inner end of the upper surface of the focus ring 69 is covered with the outer peripheral edge of the substrate G.

The base 61 is provided with a through-hole 63a, and a feeding member 70 passes through the through-hole 63a and is connected to a lower surface of the temperature regulation area of the base 61. A feeding line 71 is connected to a lower end of the feeding member 70. The feeding line 71 is connected to the radio frequency power supply 73, which is a bias power supply, via a matcher 72 that performs impedance matching. In other words, the temperature regulation area constituting the base 61 is electrically connected to the radio frequency power supply 73. The plasma processing apparatus 100 may apply radio frequency power of, for example, 13.56 MHz from the radio frequency power supply 73 to the substrate stage 60, thereby attracting ions generated by the radio frequency power supply 19 to the substrate G. In addition, the feeding member 70 may be connected to a lower surface of the base 61 and radio frequency power may be applied to the base 61.

The electrostatic chuck 67 of the substrate stage 60 includes a dielectric 671 and an electrode 672 embedded inside the dielectric 671. The electrode 672 is connected to a direct current (DC) power supply 75 via a feeding line 74. The controller 90 applies a DC voltage from the DC power supply 75 to the electrode 672 by turning on a switch (not illustrated) provided on the feeding line 74, to generate an electrostatic force (Coulomb force) in the dielectric 671. Due to this electrostatic force, the substrate G is electrostatically attracted to the support surface 67s of the electrostatic chuck 67.

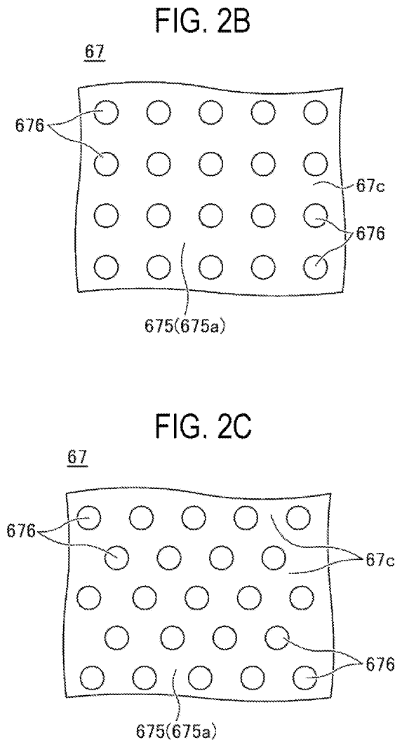

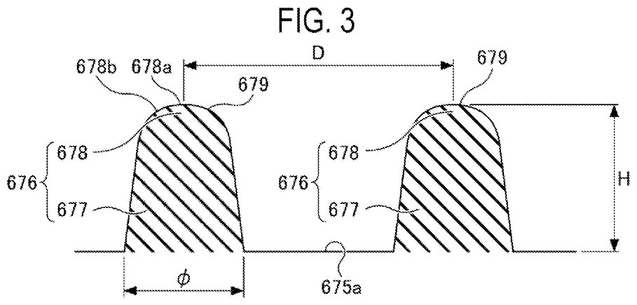

Hereinafter, a configuration of this electrostatic chuck 67 will be described in more detail. FIG. 2A is an enlarged side cross-sectional view of a part of the electrostatic chuck 67. FIG. 2B is an enlarged plan view illustrating a support surface 67s of one configuration example. FIG. 2C is an enlarged plan view illustrating a support surface 67s of another configuration example. In addition, FIG. 2A as well as FIGS. 3 and 5A to 7C to be described later have been exaggerated in vertical dimensions relative to horizontal dimensions, for clarity and ease of understanding of the disclosure.

As illustrated in FIG. 2A, the electrostatic chuck 67 is formed in a three-layer structure including a lower layer 673, an intermediate layer 674, and an upper layer 675 by thermally spraying and stacking a plurality of materials onto a base material. The base material may employ a plate made of, for example, aluminum, aluminum alloy, stainless steel, etc. This base material may be the same as the above-described base 61, or may employ a different member.

The lower layer 673 and the upper layer 675 constitute the dielectric 671 of the electrostatic chuck 67. Examples of a material forming the lower layer 673 and the upper layer 675 may include an insulating material such as alumina (Al₂O₃). On the other hand, the intermediate layer 674 constitutes the electrode 672 of the electrostatic chuck 67. Examples of a material forming the intermediate layer 674 may include a conductive material such as tungsten (W). In other words, the three-layer structure is manufactured by first thermally spraying alumina onto the base material to form the lower layer 673, then thermally spraying tungsten onto the lower layer 673 to form the intermediate layer 674, and finally thermally spraying alumina again onto the intermediate layer 674 to form the upper layer 675.

Then, a surface (reference surface 675a) of the upper layer 675 of the electrostatic chuck 67 according to the present embodiment undergoes embossing during the manufacture of the electrostatic chuck 67, so as to be provided with a plurality of protrusions 676. In particular, in the present embodiment, the plurality of protrusions 676 is formed as micro-embosses with a maximum width of 0.3 mm or less. Each of the plurality of protrusions 676 is made of a same material (e.g., alumina) as the upper layer 675, and is integrally formed with the upper layer 675. Each protrusion 676 protrudes vertically upward from the reference surface 675a to the same height. A gap 676c of a certain width is interposed between two adjacent protrusions 676.

In a plan view as illustrated in FIG. 2B, the respective protrusions 676 represent a matrix shape, with rows of the protrusions equidistantly arranged along the first direction parallel to the shorter side of the electrostatic chuck 67 and rows of the protrusions equidistantly arranged along the second direction parallel to the longer side of the electrostatic chuck 67. In addition, as illustrated in FIG. 2C, the respective protrusions 676 of two adjacent protrusion rows may be staggered in a zigzag shape.

Each protrusion 676 is formed in a circular shape in a plan view. However, the shape of each protrusion 676 in a plan view is not limited to the circular shape and may be formed in an elliptical shape or a polygonal shape such as a square shape. For example, a matrix arrangement of the plurality of square protrusions 676 may create lattice-shaped gaps 676c between the respective protrusions 676.

FIG. 3 is an enlarged side cross-sectional view illustrating the plurality of protrusions 676 of the electrostatic chuck 67. As illustrated in FIG. 3, each protrusion 676 has a base portion 677 connected to the reference surface 675a of the upper layer 675 and a head portion 678 extending to the top of the base portion 677. The head portion 678 of each protrusion 676 constitutes the support surface 67s for supporting the substrate G.

The base portion 677 is formed in a conical shape that is gradually reduced in diameter as it extends vertically upward from the reference surface 675a. In addition, the base portion 677 may also be formed in a columnar shape with a constant outer diameter in the vertical direction.

The head portion 678 is smoothly and continuously formed with respect to an outer peripheral surface of the base portion 677 to have a hemispherical curved surface. The radius of curvature of the head portion 678 is set to be smaller than the radius of the base portion 677. An apex 678a located at the uppermost vertical position of the head portion 678 is a portion that comes into direct contact with the substrate G.

At least the apex 678a of the head portion 678 corresponds to a polished portion 679 that is mirror-polished by a polishing process of a manufacturing method of the electrostatic chuck 67 to be described later. The polished portion 679 is not limited only to the apex 678a but may be continuous to a curved peripheral portion 678b of the head portion 678 surrounding the apex 678a. The surface roughness Ra of the polished portion 679 may be set in a range of 0.1 to 0.5, for example. On the other hand, the outer peripheral surface of the base portion 677 may not have the polished portion 679, and the surface roughness Ra of this outer peripheral surface is in a range of 0.5 to 1.0, for example. A smooth curved surface created by the polished portion 679 allows each protrusion 676 to support the opposing surface (lower surface) of the substrate G without causing damage thereto.

Alternatively, the apex 678a of the head portion 678 may be formed in a flat shape along the horizontal direction. In this case, the apex 678a and the curved peripheral portion 678b may be continuous through a boundary with a round shape (R-shaped boundary) formed by the polished portion 679.

The height H of each protrusion 676 from the reference surface 675a may be set appropriately in consideration of the durability of each protrusion 676, the flowability of the heat transfer gas between the electrostatic chuck 67 and the substrate G, etc. For example, it may be set in a range of 0.01 mm to 0.05 mm. In the present embodiment, the height H of each protrusion 676 is set to 0.02 mm (=20 μm).

Further, a distance D between the plurality of protrusions 676 may be set in a range of 0.2 mm to 0.5 mm. In the present embodiment, the distance D between the plurality of protrusions 676 is set to 0.35 mm (=350 μm). In addition, in this specification, the distance D between the plurality of protrusions 676 refers to a distance between the apexes 678a of adjacent protrusions 676.

Then, a diameter ϕ (maximum width) of each protrusion 676 may be set appropriately based on the distance D between the plurality of protrusions 676, which will be described later. For example, the diameter ϕ of each protrusion 676 may be set to a ratio of 0.2 times to 0.7 times with respect to the distance D between the plurality of protrusions 676. By adopting such a ratio, the electrostatic chuck 67 may stably support the substrate G with each protrusion 676 while allowing the heat transfer gas to flow smoothly through the gaps 676c. In addition, in the present embodiment, the diameter ϕ of the protrusion 676 corresponds to a diameter of the base portion 677 at a position where the base portion 677 is in contact with the reference surface 675a. Thus, the diameter of the head portion 678 of the protrusion 676 is even smaller than the diameter of the base portion 677. Further, when each protrusion 676 has a square shape, the maximum width of each protrusion 676 is the same as the diagonal length.

However, when the diameter ϕ of each protrusion 676 is less than 0.1 mm, there is a risk of difficulty in manufacturing the protrusion 676 and a decrease in the durability of the protrusion 676. Therefore, the lower limit of the diameter ϕ of each protrusion 676 may be set to 0.1 mm. Further, when the diameter ϕ of each protrusion 676 exceeds 0.3 mm, there is a possibility that places where the protrusion 676 is in the proximity of the substrate G are increased, leading to non-uniformity of the electric field, which will be described later. Thus, the diameter ϕ of each protrusion 676 may be set in a range of 0.1 mm to 0.3 mm. In the present embodiment, the diameter ϕ of the protrusion 676 is set to 0.175 mm (=175 μm).

By adopting the design of each protrusion 676 as described above, the electrostatic chuck 67 may increase the number of protrusions 676 in a 1 mm² unit while ensuring sufficient gaps 676c (distance D). With a large number of protrusions 676 in a 1 mm² unit which come into contact with the substrate G, it is possible to stably support the substrate G.

More specifically, in a plan view of the electrostatic chuck 67, the area occupancy rate of the plurality of protrusions 676 in a 1 mm² unit of the support surface 67s may be set in a range of 3% to 40%. When the occupancy rate is less than 3%, the substrate G is unstably supported, while when the occupancy rate exceeds 40%, there is a possibility that non-uniformity of temperature becomes more likely to occur when reaction by-products are deposited. In addition, the area of the plurality of protrusions 676 refers to a sum of the areas of the base portions 677 at positions where the base portions 677 are connected to the reference surface 675a in a 1 mm² unit of the support surface 67s.

Because of the shape of each protrusion 676 and the small distance D between the respective protrusions 676, it becomes difficult to emboss the electrostatic chuck 67 of the present embodiment using a conventional manufacturing method. In the conventional manufacturing method, a metal mask plate (not illustrated) having a plurality of through-holes is placed on the upper layer 675 of the electrostatic chuck 67, and alumina, which is a material for the protrusions 676, is thermally sprayed onto the placed mask plate. Thus, a manufacturing method different from the conventional manufacturing method is used to emboss the electrostatic chuck 67 of the present embodiment and to form each protrusion 676.

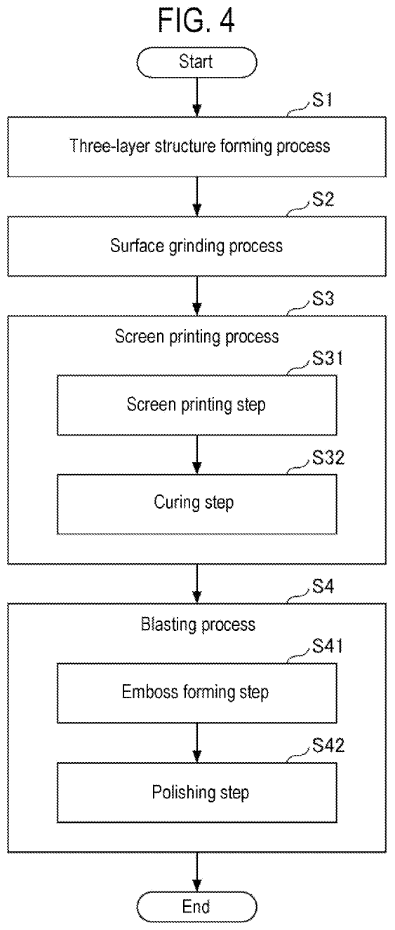

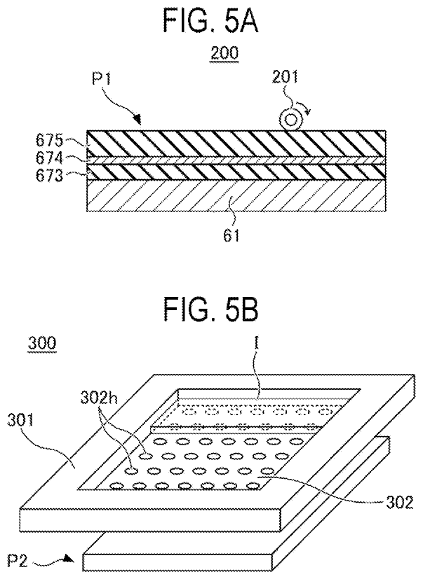

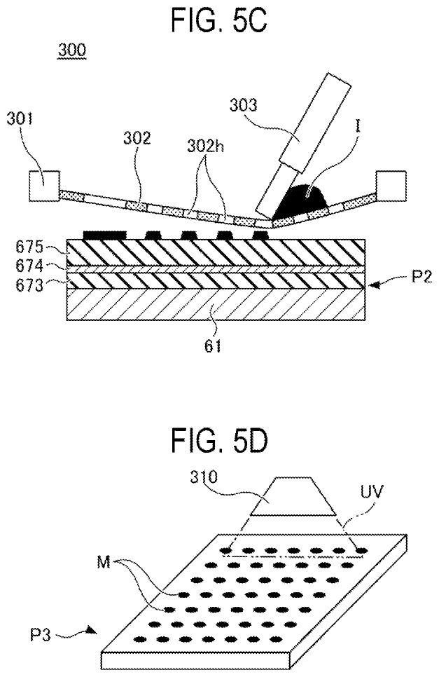

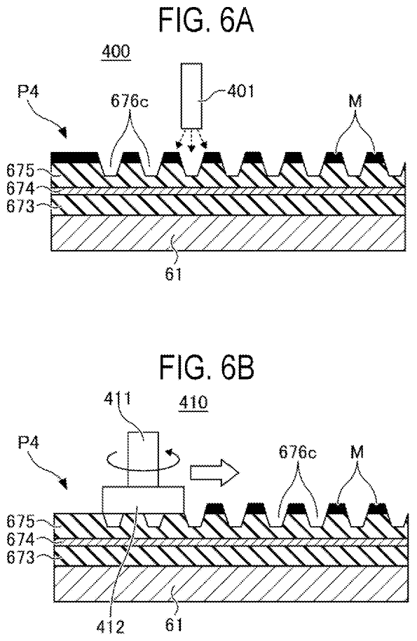

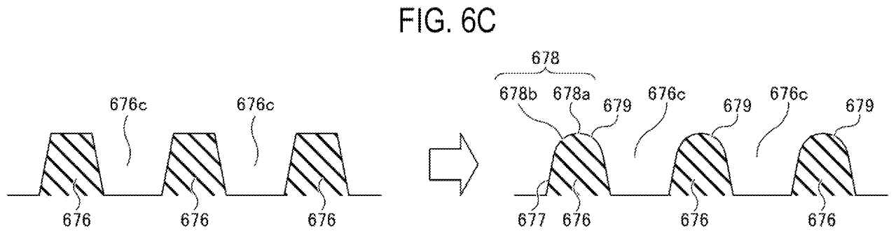

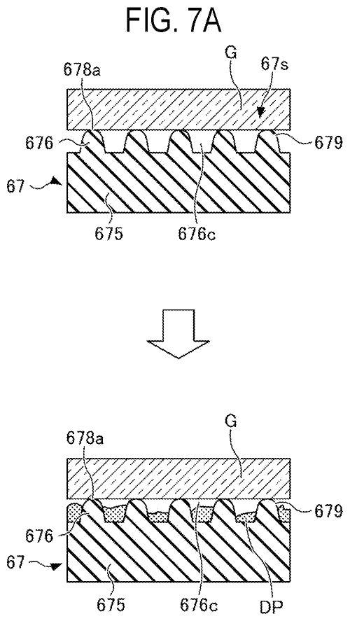

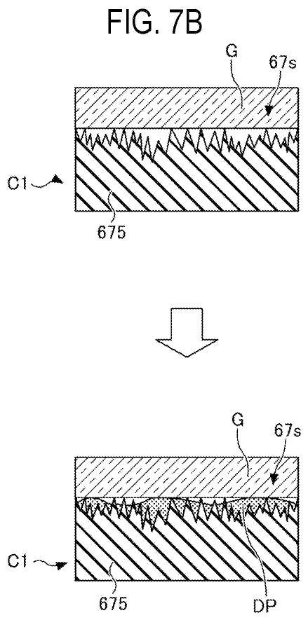

Next, the manufacturing method of the electrostatic chuck 67 having the protrusions 676 will be described with reference to FIGS. 4 to 6C. FIG. 4 is a flowchart illustrating a manufacturing method of the electrostatic chuck 67. FIGS. 5A to 5D are first to fourth explanatory diagrams illustrating the manufacturing method of the electrostatic chuck 67. FIGS. 6A and 6B are fifth and sixth explanatory diagrams illustrating the manufacturing method of the electrostatic chuck 67. FIG. 6C is an enlarged view illustrating each protrusion 676 polished by a polishing process of the manufacturing method.

As illustrated in FIG. 4, the manufacturing method of the electrostatic chuck 67 includes a three-layer structure forming process (S1), a surface grinding process (S2), a screen printing process (S3), and a blasting process (S4) in this order.

As described above, in the three-layer structure forming process (S1), a three-layer structure including the lower layer 673, the intermediate layer 674, and the upper layer 675 of the electrostatic chuck 67 is stacked onto a base material (e.g., base 61). In addition, in the three-layer structure forming process (S1), the upper layer 675 is formed thicker than the lower layer 673 in order to allow for later cutting of the upper layer 675 to create each protrusion 676.

In the surface grinding process (S2), a surface of the upper layer 675 of a precursor P1 formed by the three-layer structure forming process (S1) is processed into a flat shape. In this surface grinding process (S2), a surface grinder machine 200 as illustrated in FIG. 5A is used. For example, the surface grinder machine 200 includes a grinding wheel 201 that rotates and horizontally moves along the surface of the precursor P1 and a support (not illustrated) that supports the precursor P1. The surface grinder machine 200 grinds the upper layer 675 under the operation of the grinding wheel 201, thereby making the surface of the upper layer 675 flat.

In the screen printing process (S3) in FIG. 4, a mask is formed by performing screen printing on a precursor P2 formed by the surface grinding process (S2). Specifically, the screen printing process (S3) includes a screen printing step (S31) of applying ink I and a curing step (S32) of curing the applied ink I in this order.

In the screen printing step S31, a screen printing device 300 as illustrated in FIG. 5B is used. The screen printing device 300 includes a frame 301 in a shape of a square frame, a plate 302 set inside the frame 301, and a support (not illustrated) that supports the precursor P2 below the plate 302 in the vertical direction. The plate 302 has a plurality of holes 302h formed to correspond to the planar shape of the protrusions 676 of the electrostatic chuck 67 and the distance D between the respective protrusions 676. In other words, the diameter of each hole 302h is set to be approximately the same as the diameter ϕ of each protrusion 676, and the distance between the respective holes 302h is set to be approximately the same as the distance D between the respective protrusions 676.

In the screen printing step S31, before printing, an upper surface of the plate 302 is filled with the ink I that will serve as a mask M. A material for the ink I may be appropriately selected from among materials that are curable by irradiation of ultraviolet (UV) light and that suppress removal thereof in the blasting process (S4) to be described later. Examples of the material for the ink I may include resin materials such as polyester, polyester acrylate, epoxy acrylate, urethane acrylate, and trimethylolpropane triacrylate.

As illustrated in FIG. 5C, during screen printing, the screen printing device 300 slides a squeegee 303 along the upper surface of the plate 302 while pressing the ink I onto the plate 302 using the squeegee 303. This causes the plate 302 to come into contact with the underlying precursor P2, thus causing the ink I to be applied to the precursor P2 in a dot shape through each hole 302h in the plate 302.

Thereafter, in the curing step S32 in FIG. 4, the precursor P2 is taken out from the screen printing device 300 to cure the ink I applied in a dot shape. As illustrated in FIG. 5D, in this curing step (S32), an ultraviolet irradiation device 310 is arranged above the precursor P2 containing the ink I to irradiate the precursor P2 with ultraviolet (UV) light from the ultraviolet irradiation device. This cures the ink I, resulting in the formation of a precursor P3 having a plurality of dot-shaped masks M on a flat surface thereof. In addition, the mask M may be formed by inkjet printing and the like, but the screen printing for printing the ink in a micro-size dot shape without insufficient adhesion is preferable.

Then, in the blasting process (S4) in FIG. 4, each protrusion 676 is formed by blasting the precursor P3 having the plurality of dot-shaped masks M. Specifically, the blasting process includes an emboss forming step (S41) of spraying a blasting material to engrave the precursor P3 other than the masks M and a polishing step (S42) of polishing the respective protrusions 676 having the masks M in this order.

In the emboss forming process, a blasting device 400 as illustrated in FIG. 6A is used. The blasting device 400 includes a nozzle 401 that moves while spraying the blasting material and a support (not illustrated) that supports the precursor P3. The blasting material employs a material capable of grinding the upper layer 675 (alumina) while suppressing the grinding of the cured masks M. Examples of the blasting material may include granular glass beads, alumina, silicon carbide (SiC), and zirconia (ZrO₂).

The blasting device 400 engraves the entire upper layer 675 around the masks M by spraying the blasting material while moving the nozzle 401 and the precursor P3 relative to each other. For example, the blasting device 400 may make a unit work time for spraying the blasting material onto the surface of the upper layer 675 uniform, so that the gaps 676c having the same depth can be formed in the upper layer 675. Thus, a precursor P4 having each protrusion 676 with the mask M remaining on the head portion 678 is formed. The formation of embosses by digging-out by blasting as described above ensures that the height of the apex 678a is consistent and the embosses are less likely to be removed, compared to conventional manufacturing methods that use thermal spraying.

In the polishing step S42, the mask M on each protrusion 676 is removed, and buff polishing is performed on the protrusion 676 to form the above-described polished portion 679. For example, in the polishing step S42, a polishing device 410 as illustrated in FIG. 6B is used. The polishing device 410 includes a polishing body 411 that moves while rotating a buff 412, and a support (not illustrated) that supports the precursor P4. The buff 412 is capable of removing the mask M and polishing each protrusion 676. Examples of the buff 412 may include a fabric such as linen or cotton and a sponge such as nylon. The polishing device 410 may first use the dedicated polishing body 411 to remove the mask M, and then use another polishing body 411 to polish the head portion 678 of each protrusion 676 into a hemispherical shape.

As illustrated in FIG. 6C, an upper end of each protrusion 676, which was made into a flat shape by the surface grinding process (S2), is polished into a hemispherical shape by the above-described buff polishing. In other words, the entire head portion 678 (apex 678a and curved peripheral portion 678b) of each protrusion 676 according to the present embodiment is mirror-polished under the rotation of the buff 412 to have the polished portion 679.

The support surface 67s of the electrostatic chuck 67 manufactured by the above manufacturing method is capable of supporting the weight of the substrate G by distributing it among the plurality of embossed protrusions 676 having the same height. In particular, having the polished portion 679 at the apex 678a of each protrusion 676 that comes into direct contact with the substrate G enables each protrusion 676 to support the substrate G while eliminating the risk of damage to the substrate G.

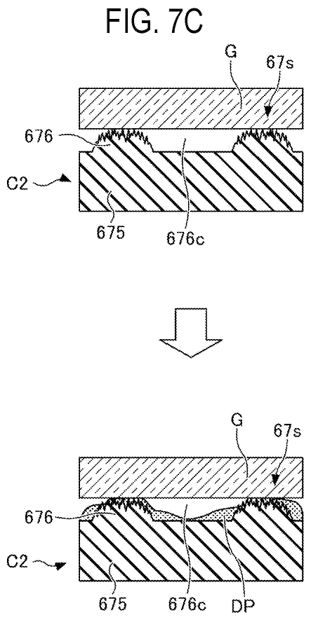

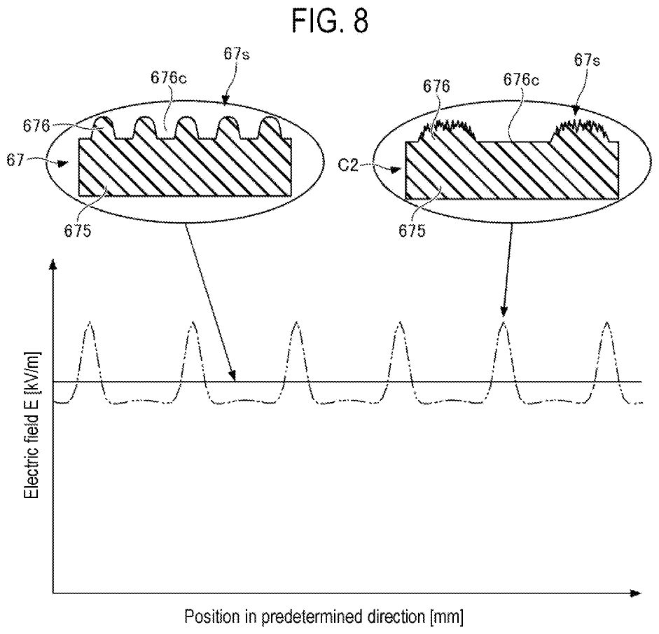

Next, the effects of supporting the substrate G by the electrostatic chuck 67 having the plurality of protrusions 676 will be described with reference to FIGS. 7A to 7C and 8. FIG. 7A is an enlarged cross-sectional view illustrating a state where the substrate G is supported by the electrostatic chuck 67 according to the present embodiment. FIG. 7B is an enlarged cross-sectional view illustrating a state where the substrate G is supported by an electrostatic chuck C1 according to a first comparative example. FIG. 7C is an enlarged cross-sectional view illustrating a state where the substrate G is supported by an electrostatic chuck C2 according to a second comparative example.

The electrostatic chuck C1 according to the first comparative example has a substantially flat support surface 67s formed by thermal spraying (or grinding) without embossing. However, as illustrated in FIG. 7B, when observed at an enlarged scale in millimeters, even the flat support surface 67s has a large number of serrated recesses and bosses. In other words, the electrostatic chuck C1 supports the substrate G on a plurality of serrated bosses constituting the support surface 67s.

When a deposit DP is generated during plasma processing and the like in the plasma processing apparatus 100, the deposit DP is accumulated on the support surface 67s of the electrostatic chuck C1 at positions of a plurality of serrated recesses. Then, the accumulation of the deposit DP in this manner results in a region of the electrostatic chuck C1 that is more in contact with the substrate G via the deposit DP and the other region that is less in contact with the substrate G due to the absence of the deposit DP. In other words, when an adjustment of the temperature of the electrostatic chuck C1 is performed, non-uniformity in heat transfer occurs between the region that comes more in contact with the substrate G and the other region that comes less in contact with the substrate G. Further, non-uniformity in the in-plane temperature distribution of the substrate G leads to non-uniformity in substrate processing and potentially results in non-uniformity in the display of a flat panel display.

On the other hand, the electrostatic chuck C2 according to the second comparative example has the support surface 67s formed by embossing. However, in the embossing according to the second comparative example, each protrusion 676 is formed on the upper layer 675 by thermal spraying as described above. Therefore, as illustrated in FIG. 7C, when observed at an enlarged scale in millimeters, a plurality of (a large number of) serrated recesses and bosses are also formed on the head portion of each protrusion 676. Thus, the electrostatic chuck C2 also supports the substrate G by a plurality of serrated bosses on each protrusion 676.

When the deposit DP occurs during plasma processing and the like in the plasma processing apparatus 100, the deposit DP is accumulated on the support surface 67s of the electrostatic chuck C2 in the gaps 676c between the plurality of protrusions 676. Therefore, the region of the electrostatic chuck C2 that comes more in contact with the substrate G via the deposit DP is reduced. However, each protrusion 676 has the region that comes more in contact with the substrate G via the deposit DP, and some differences in the heat transfer characteristics of each protrusion 676 occur between a support condition when there is the deposit DP and a support condition when there is no deposit DP.

In contrast, the support surface 67s of the electrostatic chuck 67 according to the present embodiment is formed with micro embosses (a plurality of protrusions 676) by the above-described manufacturing method. Moreover, as illustrated in FIG. 7A, when observed at an enlarged scale in millimeters, each protrusion 676 supports the substrate G by the mirror-polished apex 678a (polished portion 679).

When the deposit DP occurs due to plasma processing and the like in the plasma processing apparatus 100, the deposit DP is accumulated on the support surface 67s of the electrostatic chuck 67 in the gaps 676c between the plurality of protrusions 676, while the deposit DP is hardly accumulated on the apex 678a of each protrusion 676. As a result, the region of the electrostatic chuck 67 that comes more in contact with the substrate G via the deposit DP is reduced, and a change in the heat transfer characteristics due to the deposition of the deposit DP in each protrusion 676 is suppressed as much as possible. Thus, it can be said that the electrostatic chuck 67 is capable of continuously maintaining the uniform in-plane temperature distribution of the substrate G even after a plurality of repetitions of substrate processing, which enables a reduction in the non-uniformity of substrate processing.

FIG. 8 is a graph illustrating simulation results of an electric field along a predetermined direction of the electrostatic chucks 67 and C2. The solid line in FIG. 8 represents an electric field when supporting the substrate G by the electrostatic chuck 67 of the present embodiment, while the two-dot dashed line in FIG. 8 represents an electric field when supporting the substrate G by the electrostatic chuck C2 of the second comparative example. In addition, the electric fields of the electrostatic chucks 67 and C2 are generated by applying a predetermined radio frequency voltage from the radio frequency power supply 73 to the base 61.

In the electrostatic chuck C2 according to the second comparative example, the plurality of protrusions 676 is arranged at positions spaced apart from each other by approximately 5 mm. This is because each protrusion 676 of the electrostatic chuck C2 is formed by thermal spraying as described above. Therefore, the electric field of the electrostatic chuck C2 is formed to have a plurality of convex portions, as illustrated in FIG. 8. The position of each convex portion in the electric field corresponds to the position where each protrusion 676 of the electrostatic chuck C2 supports the substrate G. In other words, in the electrostatic chuck C2, it can be considered that there is non-uniformity in the electric field applied to the substrate G due to each protrusion 676 (a significant change in the electric field).

In contrast, in the electrostatic chuck 67 according to the present embodiment, the distance between the plurality of protrusions 676 is in the range of 0.2 mm to 0.5 mm, and the area occupancy rate of the plurality of protrusions 676 in a 1 mm² unit of the support surface 67s is in the range of 3% to 40%. In other words, the electrostatic chuck 67 supports the substrate G by a large number of very small protrusions 676 compared to the electrostatic chuck C2 according to the second comparative example, and therefore, it can be said that it supports the substrate G with the substantially flat support surface 67s.

Therefore, the electric field of the electrostatic chuck 67 is formed to change in a substantially flat shape. In other words, the electrostatic chuck 67 can support the substrate G in a state where the distribution of the electric field in the plane of the substrate G is substantially uniform (with little change in the electric field). This enables a further reduction of non-uniformity in substrate processing for the substrate G supported by the electrostatic chuck 67. In addition, non-uniformity in substrate processing depends on the specific nature of substrate processing, but refers to a change in the amount of processing applied to the substrate G. For example, when the substrate processing is etching, it refers to a significant change in the in-plane uniformity of the etching rate, or when the substrate processing is film formation, it refers to a significant change in the in-plane uniformity of the film thickness. In other words, the electrostatic chuck 67 according to the present embodiment can significantly enhance the in-plane uniformity of substrate processing due to each micro-embossed protrusion 676.

The technical ideas and effects of the present disclosure described using the above embodiments will be described below.

A first aspect of the present disclosure relates to the electrostatic chuck 67 having the support surface 67s configured to support the substrate G. The support surface 67s is configured by a plurality of protrusions 676 that is formed at the same height and is arranged in a direction in which the support surface 67s extends. A distance between the plurality of protrusions 676 adjacent to each other is in the range of 0.2 mm to 0.5 mm. In a plan view of the support surface 67s, the area occupancy rate of the plurality of protrusions 676 in a 1 mm² unit of the support surface 67s is in the range of 3% to 40%.

According to the above, the electrostatic chuck 67 can stably support the substrate G by the plurality of protrusions 676 that is formed as small as possible and is arranged at intervals. This causes the deposit DP to be sparsely deposited between the respective protrusions 676, thereby suppressing non-uniformity in the in-plane temperature distribution of the substrate G due to the deposit DP. Moreover, the support surface 67s, which is formed in a substantially flat shape by the protrusions 676, helps to avoid a high local change in the electric field, thus further reducing non-uniformity in the electric field applied to the substrate G. By these, non-uniformity in substrate processing for the substrate G supported by the electrostatic chuck 67 may be significantly reduced, leading to the suppression of non-uniformity in the display of a flat panel display.

Further, in a plan view of the support surface 67s, the ratio of the maximum width of the plurality of protrusions 676 to the distance D between the plurality of protrusions 676 is in the range of 0.2 times to 0.7 times. Thus, the electrostatic chuck 67 can form the support surface 67s with the plurality of sufficiently small protrusions 676, thereby exhibiting excellent support for the substrate G while providing the gaps 676c where the deposit DP can be deposited.

Further, the plurality of protrusions 676 is formed in a circular shape in a plan view of the support surface 67s, and the diameter of the plurality of protrusions 676 is in the range of 0.1 mm to 0.3 mm. This allows the electrostatic chuck 67 to further stably support the substrate G.

Further, the height of the plurality of protrusions 676 is in the range of 0.01 mm to 0.05 mm. Thus, the electrostatic chuck 67 may enhance the durability of each protrusion 676 while maintaining the flowability of the heat transfer gas on the lower surface of the substrate G.

Further, the electrostatic chuck 67 is configured to support a flat panel display substrate as the substrate G, and the support surface 67s is formed in a square shape in a plan view of the support surface 67s, and has a dimension in a first direction of 1,490 mm or more and a dimension in a second direction perpendicular to the first direction of 1,790 mm or more. As such, by supporting a heavy flat panel display substrate with the support surface 67s composed of the plurality of protrusions 676, it is possible to effectively suppress non-uniformity in the temperature or electric field.

Further, the electrostatic chuck 67 has the lower layer 673 and upper layer 675 made of alumina and the intermediate layer 674 constituting the electrode 672 between the lower layer 673 and the upper layer 675, and the plurality of protrusions 676 is formed integrally with the upper layer 675 and protrudes from the upper layer 675. Thus, the electrostatic chuck 67 can further promote the uniformity of the temperature and electric field transmission characteristics achieved by the plurality of protrusions 676.

Further, a second aspect of the present disclosure relates to a substrate processing apparatus (plasma processing apparatus 100) for a flat panel display, including the processing container 10 configured to perform a substrate processing on a flat panel display substrate (substrate G) and the electrostatic chuck 67 provided in the interior of the processing container 10 and having the support surface 67s configured to support the flat panel display substrate. The support surface 67s is configured by the plurality of protrusions 676 that is formed at the same height and are arranged in the direction in which the support surface 67s extends. The distance between the plurality of protrusions 676 adjacent to each other is in the range of 0.2 mm to 0.5 mm. In a plan view of the support surface 67s, the area occupancy rate of the plurality of protrusions 676 in a 1 mm² unit of the support surface 67s is in the range of 3% to 40%. Even in this case, the substrate processing apparatus can also suppress non-uniformity in substrate processing.

Further, a third aspect of the present disclosure relates to a manufacturing method of the electrostatic chuck 67 having the support surface 67s configured to support the substrate G. The support surface 67s is configured by the plurality of protrusions 676 that is formed at the same height and are arranged in the direction in which the support surface 67s extends. The manufacturing method forms the plurality of protrusions 676 by performing, in this order, (A) flattening a surface of a precursor, (B) forming a plurality of dot-shaped masks M on the flattened surface of the precursor, and (C) forming the gap 676c between the plurality of masks M by blasting, followed by removing the masks M. Even in this case, the manufacturing method of the electrostatic chuck 67 may suppress non-uniformity in substrate processing.

Further, in process (B), the plurality of masks M is formed by applying a plurality of dots of the ink I to the surface of the precursor by screen printing, and then curing the plurality of dots of the ink I by irradiating them with ultraviolet light. Thus, the manufacturing method may achieve excellent formation of the masks M corresponding to the size of the respective protrusions 676.

Further, in process (C), the precursor is engraved by spraying a blasting material on the precursor having the plurality of masks M, and then the masks M are removed by polishing the surface of the precursor. Thus, the manufacturing method can achieve precise formation of the respective protrusions 676 and gaps 676c.

Further, the distance D between the plurality of protrusions 676 adjacent to each other is in the range of 0.2 mm to 0.5 mm, and in a plan view of the support surface 67s, the area occupancy rate of the plurality of protrusions 676 in a 1 mm² unit of the support surface is in the range of 3% to 40%.

Further, in a plan view of the support surface 67s, the ratio of the maximum width of the plurality of protrusions 676 to the distance D between the plurality of protrusions 676 is in the range of 0.2 times to 0.7 times.

Further, the plurality of protrusions 676 is formed in a circular shape in a plan view of the support surface 67s, and the diameter of the plurality of protrusions 676 is in the range of 0.1 mm to 0.3 mm.

Further, the height of the plurality of protrusions 676 is in the range of 0.01 mm to 0.05 mm.

Further, the electrostatic chuck 67 is configured to support a flat panel display substrate as the substrate G, and the support surface 67s is formed in a square shape in a plan view of the support surface 67s, and has a dimension in a first direction of 1,490 mm or more and a dimension in a second direction perpendicular to the first direction of 1,790 mm or more.

Further, the electrostatic chuck 67 has the lower layer 673 and the upper layer 675 made of alumina, and the intermediate layer 674 constituting the electrode 672 between the lower layer 673 and the upper layer 675, and the plurality of protrusions 676 is formed integrally with the upper layer 675 and protrudes from the upper layer 675.

The electrostatic chuck 67, the substrate processing apparatus (plasma processing apparatus 100), and the manufacturing method of the electrostatic chuck 67 according to the embodiments disclosed herein are examples in all respects and are not restrictive. The embodiment may be modified and improved in various forms without departing from the scope of the appended claims and their gist. The items described in the above multiple embodiments may also take other configurations within a range that is not contradictory and may be combined within a range that is not contradictory.

The electrostatic chuck 67 of the present disclosure may be applied to any type of apparatuses such as atomic layer deposition (ALD), capacitively coupled plasma (CCP), inductively coupled plasma (ICP), radial line slot antenna (RLSA), electron cyclotron resonance plasma (ECR), and helicon wave plasma (HWP) apparatuses.

According to the present disclosure in some embodiments, it is possible to suppress non-uniformity of substrate processing performed on a substrate supported by an electrostatic chuck.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An electrostatic chuck having a support surface configured to support a substrate,
wherein the support surface is configured by a plurality of protrusions that is formed at a same height and is arranged in a direction in which the support surface extends,
wherein a distance between the plurality of protrusions adjacent to each other is in a range of 0.2 mm to 0.5 mm, and
wherein, in a plan view of the support surface, an area occupancy rate of the plurality of protrusions in a 1 mm² unit of the support surface is in a range of 3% to 40%.

2. The electrostatic chuck of claim 1, wherein, in the plan view of the support surface, a ratio of a maximum width of the plurality of protrusions to the distance between the plurality of protrusions is in a range of 0.2 times to 0.7 times.

3. The electrostatic chuck of claim 2, wherein the plurality of protrusions is formed in a circular shape in the plan view of the support surface, and
wherein a diameter of the plurality of protrusions is in a range of 0.1 mm to 0.3 mm.

4. The electrostatic chuck of claim 3, wherein the height of the plurality of protrusions is in a range of 0.01 mm to 0.05 mm.

5. The electrostatic chuck of claim 1, wherein the height of the plurality of protrusions is in a range of 0.01 mm to 0.05 mm.

6. The electrostatic chuck of claim 1, wherein the electrostatic chuck is configured to support a flat panel display substrate as the substrate, and
wherein the support surface is formed in a square shape in the plan view of the support surface, and has a dimension in a first direction of 1,490 mm or more and a dimension in a second direction perpendicular to the first direction of 1,790 mm or more.

7. The electrostatic chuck of claim 1, wherein the electrostatic chuck has a lower layer and an upper layer made of alumina, and an intermediate layer constituting an electrode between the lower layer and the upper layer, and
wherein the plurality of protrusions is formed integrally with the upper layer and protrudes from the upper layer.

8. A substrate processing apparatus for a flat panel display, comprising:
a processing container configured to perform a substrate processing on a flat panel display substrate; and
an electrostatic chuck provided inside the processing container and having a support surface configured to support the flat panel display substrate,
wherein the support surface is configured by a plurality of protrusions that is formed at a same height and is arranged in a direction in which the support surface extends,
wherein a distance between the plurality of protrusions adjacent to each other is in a range of 0.2 mm to 0.5 mm, and
wherein, in a plan view of the support surface, an area occupancy rate of the plurality of protrusions in a 1 mm² unit of the support surface is in a range of 3% to 40%.

9. A manufacturing method of an electrostatic chuck having a support surface configured to support a substrate,
wherein the support surface is configured by a plurality of protrusions that is formed at a same height and is arranged in a direction in which the support surface extends, and
wherein the manufacturing method forms the plurality of protrusions by performing, in this order,
(A) flattening a surface of a precursor,
(B) forming a plurality of dot-shaped masks on the flattened surface of the precursor, and
(C) forming a gap between the plurality of masks by blasting, followed by removing the masks.

10. The manufacturing method of claim 9, wherein in (B), the plurality of masks is formed by applying a plurality of dots of ink to the surface of the precursor by screen printing, and then curing the plurality of dots of the ink by irradiating the dots with ultraviolet light.

11. The manufacturing method of claim 9, wherein in (C), the precursor having the plurality of masks is engraved by spraying a blasting material against the precursor, and then the masks are removed by polishing the surface of the precursor.

12. The manufacturing method of claim 9, wherein a distance between the plurality of protrusions adjacent to each other is in a range of 0.2 mm to 0.5 mm, and
wherein, in a plan view of the support surface, an area occupancy rate of the plurality of protrusions in a 1 mm² unit of the support surface is in a range of 3% to 40%.

13. The manufacturing method of claim 10, wherein a distance between the plurality of protrusions adjacent to each other is in a range of 0.2 mm to 0.5 mm, and
wherein, in a plan view of the support surface, an area occupancy rate of the plurality of protrusions in a 1 mm² unit of the support surface is in a range of 3% to 40%.

14. The manufacturing method of claim 11, wherein a distance between the plurality of protrusions adjacent to each other is in a range of 0.2 mm to 0.5 mm, and
wherein, in a plan view of the support surface, an area occupancy rate of the plurality of protrusions in a 1 mm² unit of the support surface is in a range of 3% to 40%.

15. The manufacturing method of claim 12, wherein, in the plan view of the support surface, a ratio of a maximum width of the plurality of protrusions to the distance between the plurality of protrusions is in a range of 0.2 times to 0.7 times.

16. The manufacturing method of claim 15, wherein the plurality of protrusions is formed in a circular shape in the plan view of the support surface, and
wherein a diameter of the plurality of protrusions is in a range of 0.1 mm to 0.3 mm.

17. The manufacturing method of claim 12, wherein the height of the plurality of protrusions is in a range of 0.01 mm to 0.05 mm.

18. The manufacturing method of claim 12, wherein the electrostatic chuck is configured to support a flat panel display substrate as the substrate, and
wherein the support surface is formed in a square shape in the plan view of the support surface, and has a dimension in a first direction of 1,490 mm or more and a dimension in a second direction perpendicular to the first direction of 1,790 mm or more.

19. The manufacturing method of claim 12, wherein the electrostatic chuck has a lower layer and an upper layer made of alumina, and an intermediate layer constituting an electrode between the lower layer and the upper layer, and
wherein the plurality of protrusions is formed integrally with the upper layer and protrudes from the upper layer.
